(19) United States
(12) Patent Application Publication
(10) Pub. No.: US 2007/0155154 A1
(43) Pub. Date: Jul. 5, 2007

(54) System and method for solder bumping using a disposable mask and a barrier layer

(76) Inventors: Mengzhi Pang, Phoenix, AZ (US); Isao Yamada, Tokyo (JP)

Correspondence Address: Buckley, Maschoff & Talwalkar LLC;Attorneys for INTEL Corporation, Five Elm Street, New Canaan, CT, 06840, US

(21) Appl. No.: 11/321,104

(22) Filed: Dec. 29, 2005

(51) Int. Cl. H01L 21/44; H01L 23/48; H01L 23/52

(52) U.S. Cl. 438/613; 257/778

(57) ABSTRACT

According to some embodiments, a method, an apparatus, and a system are provided. In some embodiments, the method includes applying solder resist material on a surface of a substrate, applying a barrier layer on top of the solder resist material, applying at least one layer of mask material on top of the barrier layer, subjecting solder placed in an opening formed through the solder resist material, the barrier layer, and the mask material to a reflow process, and removing the mask material and the barrier layer from at least an area adjacent to the solder bump.

### BACKGROUND

Regarding semiconductor devices, there is a desire to increase interconnect density and electrical performance of IC packages. For example, there is a push to provide flip chips having ever smaller bump pitch. Flip chip technologies, including “Controlled Collapse Chip Connection” (C4) technology, may provide a proven mechanism for electrically connecting a die to a mounting substrate.

There is a desire to decrease bump pitch for high I/O and high power chips. The push for reduced bump pitch may result in corresponding decreases in via size opening, bump size, bump height, etc. Consequently, in some instances, a process of creating solder bumps (i.e., solder bumping)

Reliability of a flip chip may be impacted by the construction of the solder bumps and other assembly factors, including understanding and controlling the systems and methods to create the solder bumps. Variations in a bumping process or aspects thereof may result in a failure and/or reduced reliability of a flip chip device.

### BRIEF DESCRIPTION OF THE DRAWINGS

FIG. 1 is a flow chart of an exemplary process, in accordance with some embodiments herein;

FIGS. 2A-2J are exemplary illustrations of an apparatus, at various stages of a manufacturing process, according to some embodiments hereof;

FIGS. 3A-3H are exemplary illustrations of an apparatus, at various stages of a manufacturing process, according to some embodiments hereof; and

FIG. 4 is an exemplary illustration of a system, according to some embodiments hereof.

### DETAILED DESCRIPTION

The several embodiments described herein are solely for the purpose of illustration. Embodiments may include any currently or hereafter-known versions of the elements described herein. Therefore, persons in the art will recognize from this description that other embodiments may be practiced with various modifications and alterations.

Some embodiments hereof provide a manufacturing process for producing a flip chip package. In some embodiments, the flip chip is formed using a wafer substrate that has a conductive solder bump formed in an opening in solder resist material disposed on a surface of the substrate. In a process of forming the solder bump, a barrier layer is placed on top of the solder resist material that is on the substrate, and a mask material is placed on top of the barrier layer.

Placing the barrier layer between the solder resist material and the mask material, in some embodiments, may provide a mechanism for efficiently removing the mask material from the solder resist, wherein a quantity of residual mask material remaining on the solder resist is reduced, minimized, or eliminated.

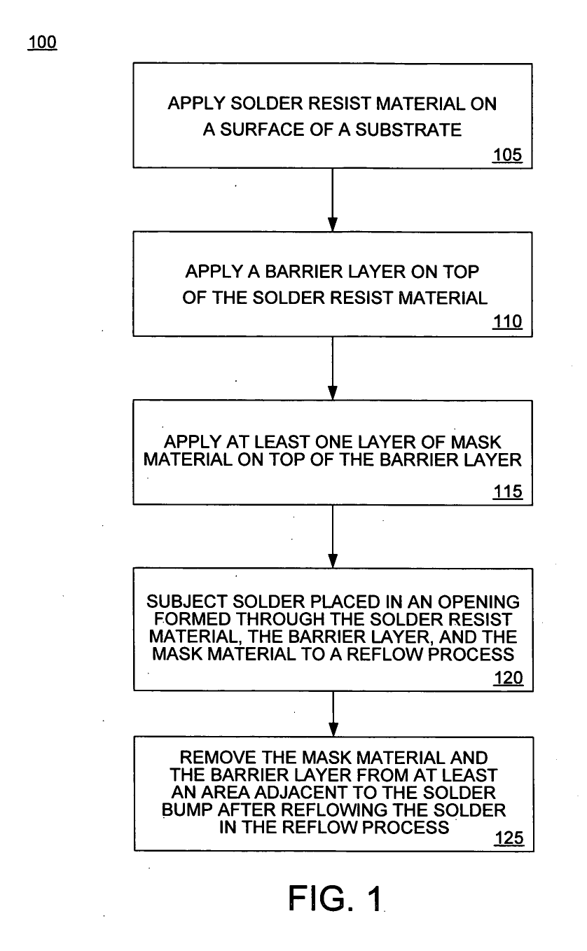

Referring to FIG. 1, there is shown an exemplary flow diagram of a manufacturing process for producing an apparatus in accordance with some embodiments hereof, generally represented by the reference numeral 100. Processes herein, including process 100, may be performed by any combination of hardware, software, and/or firmware. According to some embodiments, instructions for implementing processes, including but not limited to process 100, may be stored in executable code. The code may be stored on any suitable article or medium that is or becomes known.

At operation 105, a wafer including a substrate is created, obtained, or otherwise provided for use in process 100. The substrate may be produced or formed using any number of methods of IC (integrated circuit) manufacturing processes that result in a substrate suitable and compatible with the various aspects and embodiments herein.

In some embodiments, the substrate may include a single or multilayer dielectric material. The dielectric material may be selected to include any number of materials compatible with and suitable for IC manufacturing processes, not limited to those explicitly discussed herein. Furthermore, those skilled in the art are familiar with the range of substrate materials compatible with the various embodiments herein. In some embodiments, the substrate may include build-up layers of ABF (Ajinomoto Build-Up Film) or other organic film layer.

At operation 110, a barrier layer is provided on top of the solder resist material. The barrier layer may be deposited, created, formed, and otherwise disposed on top of the solder resist material in a variety of methods and processes, including those consistent and compatible with IC manufacturing techniques and other aspects herein. In some embodiments a thin barrier layer may be applied to the top of the solder resist using an autocatalytic process. For example, an electroless Cu (copper) deposition process may be used to plate a thin layer of Cu on top of the solder resist material.

The barrier layer may be placed on top of the solder resist material using a number and variety of techniques to apply the barrier layer comprising a number of different materials

At operation 115, at least one layer of mask material is applied, placed, deposited, disposed, or otherwise provided on top of the barrier layer. In this manner, the barrier layer is between and separates the mask material from the solder resist material.

In some embodiments herein, the mask material comprises a disposable mask. In some embodiments, a disposable mask may be used to facilitate control of the solder bumping processes of the various embodiments herein. For example, a disposable mask that is used for a single run of a solder bumping process may provide precise mask coverage and solder bumps having consistent features (e.g., height, size, etc.) since the disposable mask is not degraded due to repeated use thereof.

In some embodiments hereof, the barrier layer may include materials that can be effectively and/or efficiently removed from the mask material such that substantially all of the mask material may be removed from the barrier layer. In some embodiments, the mask material is removed using techniques, processes, and methods consistent with IC manufacturing flows.

At operation 120, solder placed in an opening that is formed through the mask material, the barrier layer, and the solder resist is subjected to a reflow process. In some embodiments, the solder may be placed into the opening using a solder printing technique to place a solder paste in the opening. It should be appreciated that the solder should be compatible with IC manufacturing processes and the various embodiments herein, and may be placed in the opening through the mask material, barrier layer, and solder resist material in a variety of methods and techniques.

The solder is subjected to a thermal reflow process to create a solder bump in the opening formed through the mask material, barrier layer, and solder resist material. In some embodiments, the solder bump may have a substantially spherical upper surface. Sidewalls of the opening may act to contain the solder therebetween during the reflow process.

At operation 125, the mask material and the barrier layer are removed from the solder resist material. Removal of mask material and the barrier layer after the reflow process reduces or eliminates potential lift-off of solder material that may otherwise occur in an instance the mask material were removed prior to the reflow process. In some embodiments, the presence of the barrier layer facilitates the complete removal of the mask material since the barrier layer separates the mask material from the solder resist and the barrier layer may be efficiently removed from the solder resist material. In this manner, an ability of the mask material to adhere to the solder resist may be minimized or eliminated by placement of the barrier layer between the mask material and the solder resist material. For example, an interaction between the mask material and the solder resist material such as, for example, cross-linking, bonding, etc. between the different materials, may be eliminated or reduced.

In some embodiments, such as when the barrier layer comprises a metal (e.g., electroless Cu) and the solder resist material and the mask material include organic materials, the barrier layer does not readily or effectively adhere to the mask or solder resist material.

In some embodiments, the barrier layer may be removed or stripped from the solder resist material using a quick chemical etch process. In some embodiments, the mask material and/or the barrier layer may be removed from the solder resist material a chemical etch technique, a laser ablation technique, a mechanical removal technique, and combinations thereof.

In some embodiments herein, the barrier layer and the removal of mask material and barrier layer after the reflow process to create the solder bump facilitates a mechanism for providing consistent or uniform solder bumps. By controlling the size of the opening, the amount of solder placed in the opening, and effective removal of the mask material after the reflow process, the amount of solder subjected to the reflow process may be consistently maintained. Thus, consistent or uniform solder bumps may be provided in accordance with some of the embodiments herein.

In some embodiments, the height of the solder bumps created in accordance with some embodiments herein may vary about 5 micrometers (μm) or less.

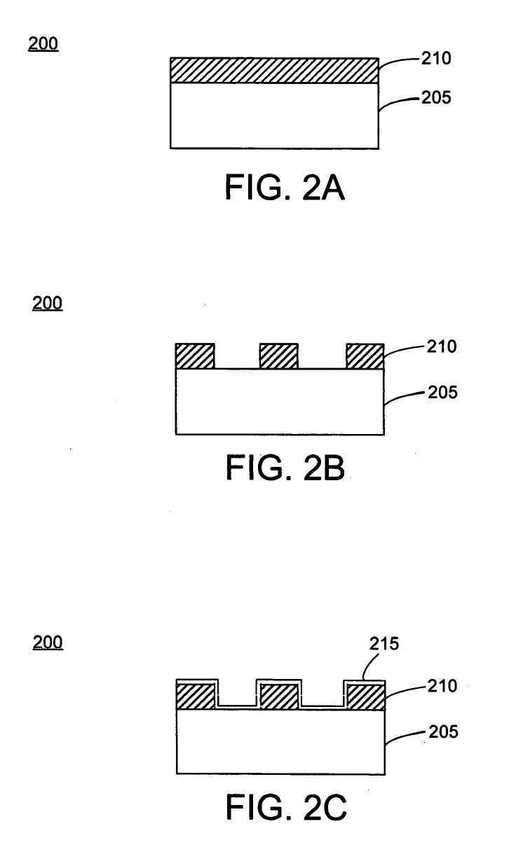

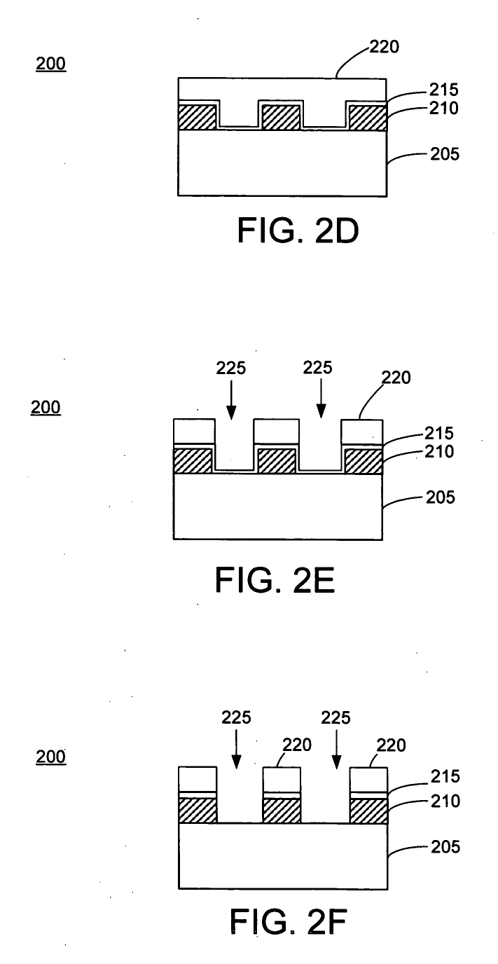

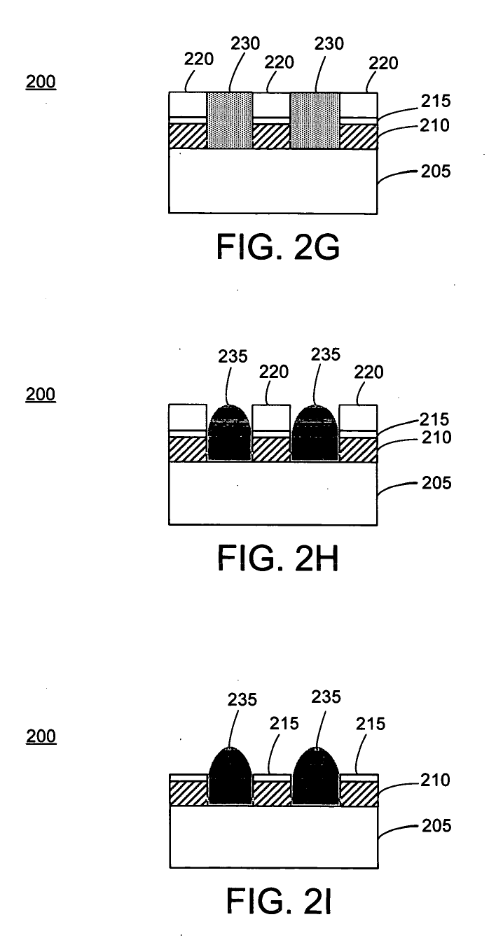

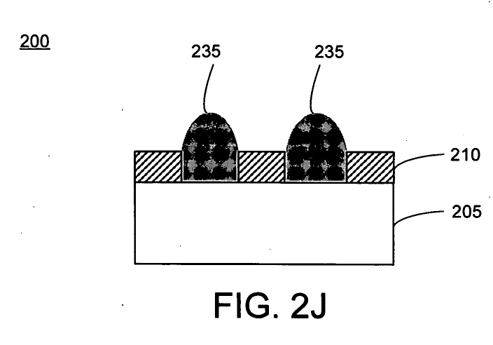

FIGS. 2A-2J provide of an apparatus, at various stages of a manufacturing process, according to some embodiments hereof. FIGS. 2A-2J may provide an illustrative flow of some of the operations of process 100. In some embodiments, one or more of FIGS. 2A-2J may correspond or relate to one or more of the operations depicted in process 100.

FIG. 2A illustrates a substrate 205 having at least one layer of solder resist material 210 on a surface thereof. In compliance with IC manufacturing process and other aspects herein, the solder resist material may be applied or otherwise provided by a variety of techniques and processes. FIG. 2B illustrates wafer 200 wherein at least portions of the at least one layer of solder resist material 210 has been removed therefrom. In some embodiments, portions of the at least one layer of solder resist material 210 may be selectively removed using any of a number of suitable processes.

FIG. 2C is an exemplary illustration of wafer 200 showing a barrier layer 215 applied on top of the at least one layer of solder resist material 210. Barrier layer 215 may be applied or otherwise provided to substantially all exposed surfaces of solder resist material 210, including vertically and horizontally oriented surfaces. Barrier layer 215 is applied on top of the portions of substrate 205 not covered or blocked by the at least one layer of solder resist material 210.

FIG. 2D illustrates an exemplary wafer 200 at stage of processing wherein at least one layer of mask material 220 is applied on top of barrier layer 215. As shown, barrier layer 215 is located between the at least one layer of mask material 220 and the at least one layer of solder resist material 210.

At FIG. 2E, an opening 225 is formed through the at least one layer of mask material 220. As shown, the opening extends through the at least one layer of mask material 220 to the barrier layer adjacent substrate 204. Opening 225 may be formed using a chemical process, mechanical process, or combinations thereof.

FIG. 2F further illustrates wafer 200 where barrier layer 215 that is not covered by the at least one layer of mask material 220 is removed from the wafer. Illustratively, barrier layer 215 is removed from a bottom surface of opening 225. As shown, opening 225 extends through the at least one layer of mask material 220, barrier layer 215, and the at least one layer of solder resist material 210 to substrate 205. Opening 225 may be formed using a chemical process, mechanical process, or combinations thereof.

FIG. 2G illustrates wafer 200 having a quantity of solder paste 230 placed, printed, squeegeed, or otherwise disposed in openings 225. In some embodiments, solder 230 may be provided in the openings in the form of a paste. In some embodiments, solder 230 may be provided in a lithography operation.

FIG. 2H illustrates wafer 200 after it has undergone or been subjected to a thermal reflow process to create a number of solder bumps 235. Solder bumps 235 may be formed due to the temperatures provided in the thermal reflow process. The specific temperatures may vary depending on the reflow process, on the composition of solder 230, and environmental conditions.

FIG. 21 illustrates wafer 200 wherein the at least one layer of mask material 220 is removed from barrier layer 215. The at least one layer of mask material 220 is removed from at least an area adjacent solder bump 235. In some embodiments, the at least one layer of mask material 220 may be completely removed from all areas of wafer 200. In some embodiments, the removal of the at least one layer of mask material 220 may be facilitated by the tendency, or lack of a tendency, for the at least one layer of mask material 220 to adhere to barrier layer 215.

FIG. 2J illustrates wafer 200 where the barrier layer 215 is removed from the at least one layer of solder resist material 210. The barrier layer 215 is removed from at least an area adjacent solder bump 235. In some embodiments, barrier layer 215 may be completely removed from all areas of wafer 200. In some embodiments, the removal of barrier layer 215 may be facilitated by a tendency, or lack thereof, for the at least one layer of solder resist 210 to adhere to barrier layer 215.

Accordingly, FIGS. 2A-2J illustrate exemplary stages of manufacture regarding an apparatus or device 200.

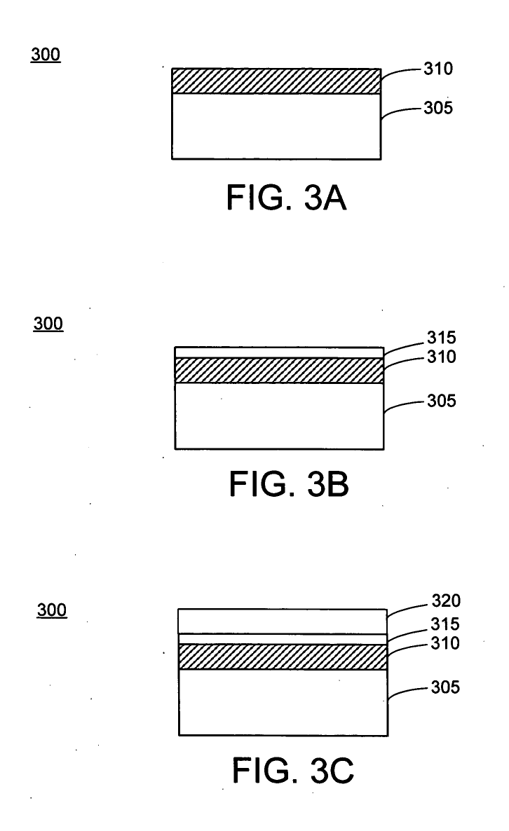

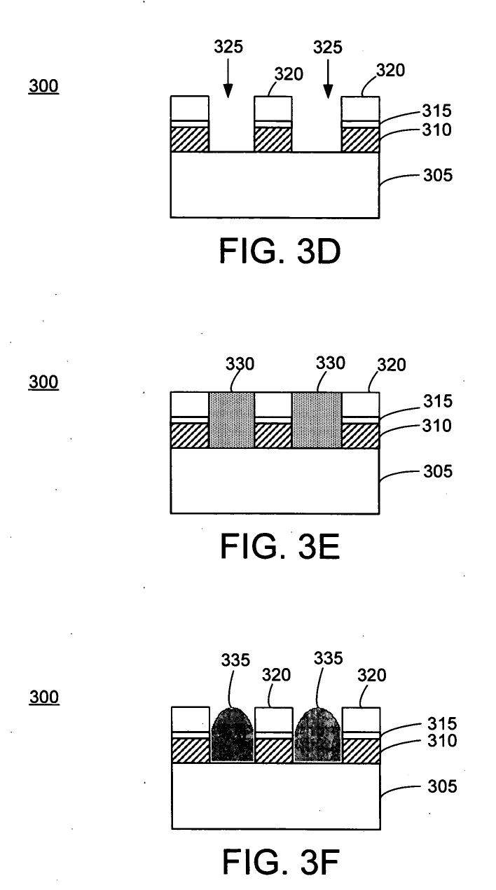

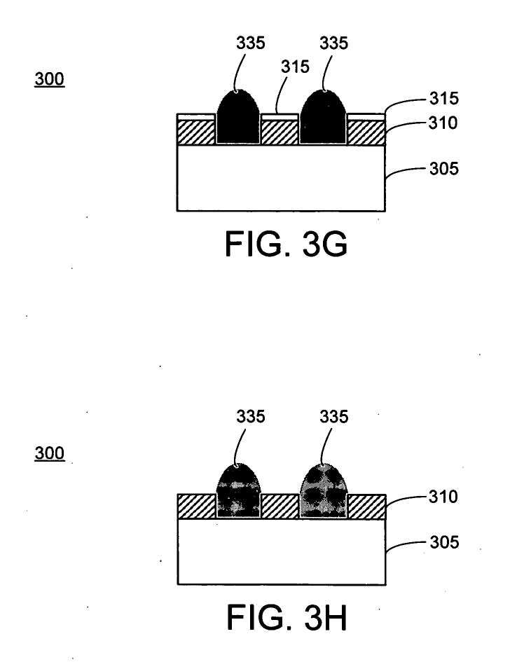

FIGS. 3A-3H provide of an apparatus, at various stages of a manufacturing process, according to some embodiments hereof. FIGS. 3A-3H, in some embodiments, may provide an illustrative flow of some of the operations of process 100. In some embodiments, one or more of FIGS. 3A-3H may correspond or relate to one or more of the operations depicted in process 100. FIGS. 3D-3H also, in part, correspond to FIGS. 2F-2J.

FIG. 3A illustrates a substrate 305 having at least one layer of solder resist material 310 on a surface thereof. The solder resist material may be applied or otherwise provided by a variety of techniques and processes. FIG. 3B illustrates wafer 300 wherein a barrier layer 315 is applied on top of the at least one layer of solder resist material 310. Barrier layer 315 may be applied or otherwise provided on substantially all upper surfaces or exposed surfaces of solder resist material 310, including horizontal surfaces thereof.

FIG. 3C illustrates exemplary wafer 300 at a stage of processing wherein at least one layer of mask material 320 is applied on top of barrier layer 315. As shown, barrier layer 315 is located between the at least one layer of mask material 320 and the at least one layer of solder resist material 310.

At FIG. 3D (similar to FIG. 2F), an opening 325 is formed through the at least one layer of mask material 320, barrier layer 315, and the at least one layer of solder resist material 310. As shown, opening 325 extends through the at least one layer of mask material 320, barrier layer 315, and the at least one layer of solder resist material 310 to substrate 305. Opening 325 may be formed using a chemical process, mechanical process, or combinations thereof.

FIG. 3E (similar to FIG. 2G) illustrates wafer 300 having a quantity of solder 330 placed, printed, squeegeed, or otherwise disposed in openings 325. In some embodiments, solder 330 may be provided in the openings in the form of a paste. In some embodiments, solder 330 may be provided in a lithography operation.

FIG. 3F (similar to FIG. 2H) illustrates wafer 300 after it has undergone or been subjected to a thermal reflow process to create a number of solder bumps 335. Solder bumps 335 may be formed due to the operating temperatures provided in the thermal reflow process.

FIG. 3G (similar to FIG. 21) illustrates wafer 300 wherein the at least one layer of mask material 320 is removed from barrier layer 315. The at least one layer of mask material 320 is removed from at least an area adjacent solder bump 335. In some embodiments, the at least one layer of mask material 320 may be completely removed from all areas of wafer 300. In some embodiments, the removal of the at least one layer of mask material 320 may be facilitated by a tendency of the at least one layer of mask material 320 not to adhere to barrier layer 315.

FIG. 3H (similar to FIG. 2J) illustrates wafer 300 where the barrier layer 315 is removed from the at least one layer of solder resist material 310. Barrier layer 315 is removed from at least an area adjacent solder bump 335. In some embodiments, barrier layer 315 may be completely removed from all areas of wafer 300. In some embodiments, the removal of barrier layer 315 may be facilitated by a tendency of the at least one layer of solder resist 310 not to adhere to barrier layer 215. In this manner, the at least one layer of mask material 320 may be completely removed from the at least one layer of solder resist material 310

In some embodiments herein, an opening created through the mask material, the barrier layer, and the solder resist material may be done substantially at the same time. For example, the opening through the mask material, the barrier layer, and the solder resist material may be made using a laser beam in a laser projection patterning (LPP) process. Other methods, techniques, and processes may be used to create the opening through the the mask material, the barrier layer, and the solder resist material. In this manner, alignment of the opening through the mask material, the barrier layer, and the solder resist material may coincide with each other (i.e., align).

In some embodiments, an alignment tolerance of about 5 μm or less may be achieved for the opening through the various layers 210 (310), 215 (315), and 220 (320) at the same time.

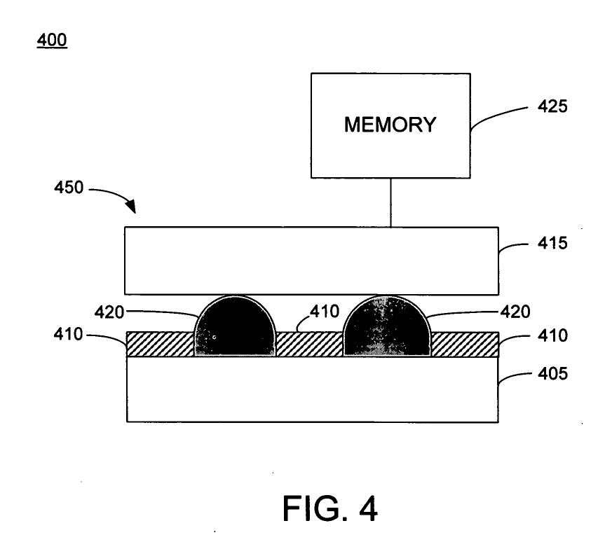

FIG. 4 is an exemplary depiction of a system 400 including an apparatus, for example a flip chip IC package 450, having solder bumps 420 created in accordance with some embodiments herein. Flip chip 450 may be connected to a memory 425. Those in the art should appreciate that system 400 may include additional, fewer, or alternative components to flip chip 450 and memory 425. Memory 425 may comprise any type of memory for storing data, including but not limited to a Single Data Rate Random Access Memory, a Double Data Rate Random Access Memory, or a Programmable Read Only Memory.

In some embodiments, an IC device 415 is placed in contact with solder bumps 420. IC device 415 may contact solder bumps 420 at conductive connectors, pads, and traces (not shown) to provide electrical connectivity between IC device 415 and substrate 405, through solder bumps 420. In some embodiments, an apparatus, system, and device may include solder bumps 420 created by removing a mask material (not shown) (e.g., a disposable mask material) previously disposed on top of a barrier layer (not shown) that was disposed on top of solder resist material 410 and subsequently removed therefrom after a reflow process used to create solder bumps 420.

It should be appreciated that the drawings herein are illustrative of various aspects of the embodiments herein, not exhaustive of the present disclosure. For example, FIGS. 2-4 are simplified for considerations of clarity. While not shown, it should be appreciated that FIGS. 2-4 may include under bump metallization (UBM), underfill materials, and other flip chip components and attributes.

The several embodiments described herein are solely for the purpose of illustration. Persons in the art will recognize from this description that other embodiments may be practiced with modifications and alterations limited only by the claims.

What is claimed is:

1. A method comprising:
applying solder resist material on a surface of a substrate;
applying a barrier layer on top of the solder resist material;
applying at least one layer of mask material on top of the barrier layer;
subjecting solder placed in an opening formed through the solder resist material, the barrier layer, and the mask material to a reflow process; and
removing the mask material and the barrier layer from at least an area adjacent to the solder bump after reflowing the solder in the reflow process.

2. The method of claim 1, wherein the mask material comprises a disposable mask material.

3. The method of claim 1, wherein the solder resist material is not photosensitive.

4. The method of claim 1, wherein the opening is about 70 micrometers (μm) or less in diameter.

5. The method of claim 1, further comprising: reflowing solder located in a plurality of openings formed through both the solder resist material and the mask material to create a plurality of solder bumps; and
removing the mask material after the reflowing of the solder in the plurality of openings.

6. The method of claim 5, wherein in a wherein a variance in height for the plurality of solder bumps is about 10 μm or less.

7. The method of claim 6, wherein the variance in height is about 5 μm or less.

8. The method of claim 1, wherein the opening through both the solder resist material and the mask material is created by irradiating both the solder resist material and the mask material using a laser beam.

9. The method of claim 1, wherein the solder is placed in the opening by a solder paste printing process.

10. The method of claim 1, wherein the removing of the mask material is accomplished using at least one of a chemical technique and a laser ablation technique.

11. The method of claim 1, further comprising at least one of:
applying a solder resist material on the surface of the substrate, applying the mask material on top of the solder resist material, placing the solder in the solder resist opening, and combinations thereof.

12. An apparatus comprising:
a substrate;
at least one layer of solder resist material on a surface of the substrate; and
a solder bump, wherein the solder bump is created by:
applying a barrier layer on top of the solder resist material;
applying at least one layer of mask material on top of the barrier layer;
subjecting solder placed in an opening through the at least one layer of solder resist material, the barrier layer, and the at least one layer of mask material to a reflow process; and
removing the mask material and the barrier layer from at least an area adjacent to the solder bump after reflowing the solder in the reflow process.

13. The apparatus of claim 12, wherein, wherein the mask material comprises a disposable mask material.

14. The apparatus of claim 12, wherein the solder resist material is not photosensitive.

15. The apparatus of claim 12, wherein the opening is about 70 micrometers (μm) or less in diameter.

16. The apparatus of claim 12, further comprising:
a plurality of solder bumps in a plurality of openings formed through both the solder resist material and the at least one layer of mask material, wherein the at least one layer of mask material is removed after reflowing of the solder in the reflow process.

17. The apparatus of claim 16, wherein in a wherein a variance in height for the plurality of solder bumps is about 10 μm or less.

18. The apparatus of claim 17, wherein the variance in height is about 5 μm or less.

19. The apparatus of claim 12, wherein the opening through both the solder resist material and the mask material is created by irradiating both the solder resist material and the mask material using a laser beam.

20. The apparatus of claim 12, wherein the solder is placed in the opening by a solder paste printing process.

21. The apparatus of claim 12, wherein the removing of the mask material is accomplished using at least one of a chemical technique and a laser ablation technique.

22. A system comprising:
a substrate;
at least one layer of solder resist material on a surface of the substrate; and
a solder bump, wherein the solder bump is created by:
applying a barrier layer on top of the solder resist material;
applying at least one layer of mask material on top of the barrier layer;
subjecting solder placed in an opening through the at least one layer of solder resist material, the barrier layer, and the at least one layer of mask material to a reflow process; and
removing the mask material and the barrier layer from at least an area adjacent to the solder bump after reflowing the solder in the reflow process;
an integrated circuit (IC) device attached to the solder bump; and
a memory, wherein the memory is a Double Data Rate Random Access Memory.

23. The system of claim 22, wherein the solder resist opening is about 70 micrometers (μm) or less in diameter.

24. The system of claim 22, wherein the IC is a microprocessor.
